(19) United States
(12) Patent Application Publication
(10) Pub. No.: US 2026/0040531 A1
(43) Pub. Date: Feb. 5, 2026

(54) SEMICONDUCTOR AND METHOD OF MANUFACTURING THE SAME

(71) Applicant: NANYA TECHNOLOGY CORPORATION, New Taipei City (TW)

(72) Inventors: Chih-Wei HUANG, New Taipei City (TW); Hsu-Cheng FAN, New Taipei City (TW); En-Jui LI, New Taipei City (TW); Chih-Yu YEN, New Taipei City (TW)

(21) Appl. No.: 18/788,156

(22) Filed: Jul. 30, 2024

(51) Int. Cl. H10B 12/00

(52) U.S. Cl. CPC H10B 12/482; H10B 12/02; H10B 12/485

(57) ABSTRACT

Embodiments of this disclosure provide a semiconductor structure, including a substrate, a bit line structure disposed over the substrate, a spacer structure disposed on and extending along a sidewall of the bit line structure, and a bit line contact disposed in each of the plurality of active areas and contacting a bottom portion of the second spacer. The spacer structure includes a first spacer surrounding a sidewall of the bit line structure and a second spacer surrounding a lower portion of a sidewall of the first spacer. A top surface of the first spacer is higher than a top surface of the second spacer. Additionally, a method of manufacturing a semiconductor structure is also disclosed in this disclosure.

### BACKGROUND

### Field of Invention

The present disclosure relates to a semiconductor structure and a method of manufacturing the same.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. Due to shrinking the size of the semiconductor structure, in addition to increasing the difficulty of the manufacturing process, the components in the semiconductor structures are also prone to leakage resulting from too close distances.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A substrate including a plurality of active areas and a plurality of insulation areas is provided, and each of the plurality of insulation areas is located between adjacent two of the plurality of active areas. Each of a plurality of bit line contacts is formed in each of the active areas, respectively, and each of a plurality of bit line structures is formed on each of the plurality of bit line contacts, respectively. A first oxide layer is deposited covering the plurality of bit line structures. A second oxide layer is deposited on the first oxide layer. A photoresist layer is formed to completely cover the second oxide layer. An upper portion of the second oxide layer is removed to expose an upper portion of the first oxide layer.

In some embodiments, removing the upper portion of the second oxide layer includes the following steps. A planarization process is performed on the photoresist layer until exposing a top surface of the second oxide layer after forming the photoresist layer. The upper portion of the second oxide layer is etched to expose the upper portion of the first oxide layer.

In some embodiments, the method further includes the following steps. Two contact spacers are formed after depositing the first oxide layer, and each of the two contact spacers is respectively located on opposite sides of each of the plurality of bit line contacts and surrounded by the first oxide layer.

In some embodiments, the method further includes the following steps. The photoresist layer is removed. A top portion of the first oxide layer on each of the plurality of bit line structures is etched until exposing each of the two contact spacers. Each of the plurality of bit line structures is shortened with a height after etching the top portion of the first oxide layer.

In some embodiments, the top portion of the first oxide layer and each of the plurality of bit line structures are rounded after etching the top portion of the first oxide layer.

In some embodiments, a stepwise contour at a top portion of the second oxide layer on the exposed upper portion of the first oxide layer is become into a smooth tapered contour at the top portion of the second oxide layer on the exposed upper portion of the first oxide layer after etching the top portion of the first oxide layer.

In some embodiments, the method further includes the following steps. A first dielectric layer is conformally deposited on each of the plurality of bit line structures, the exposed two contact spacers, a portion of the plurality of active areas and a portion of each the plurality of insulation areas after removing the photoresist layer. A sacrificial layer is deposited on the first dielectric layer to completely cover each of the plurality of bit line structures. A top portion of each of the plurality of bit line structures, the top portion of the first oxide layer, a top portion of the first dielectric layer and a top portion of the sacrificial layer are removed.

In some embodiments, a top surface of each of the bit line structures, a top surface of the first oxide layer and a top surface of the first dielectric layer are coplanar after removing the top portion of each of the plurality of bit line structures.

In some embodiments, the method further includes the following steps. The sacrificial layer after removing the top portion of each of the plurality of bit line structures. A plurality of cell contacts are formed, and each of the plurality of cell contacts respectively is located between adjacent two of the plurality of bit line structures. A bottom portion of each of the plurality of cell contacts is contact with each of the plurality of active areas.

In some embodiments, the method further includes the following steps. An upper portion of the first dielectric layer, the upper portion of the first oxide layer and an upper portion of each of the plurality of bit line structures during forming the plurality of cell contacts are partially removed. A top portion of the first dielectric layer, a top portion of the second oxide layer, the top portion of the first oxide layer and the top portion of each of the plurality of bit line structures are collectively formed a rocket shape.

In some embodiments, the method further includes the following steps. A plurality of landing pads are formed on each of the plurality of cell contacts. A second dielectric layer is formed on each of the plurality of the bit line structures to separate each of the landing pads from each other.

Embodiments of this disclosure provide a semiconductor structure, including a substrate, a bit line structure disposed over the substrate, a spacer structure disposed on and extending along a sidewall of the bit line structure, and a bit line contact disposed in each of the plurality of active areas and contacting a bottom portion of the second spacer. The spacer structure includes a first spacer surrounding a sidewall of the bit line structure and a second spacer surrounding a lower portion of a sidewall of the first spacer. A top surface of the first spacer is higher than a top surface of the second spacer.

In some embodiments, the semiconductor structure further includes a top surface of the first spacer is higher than a top surface of the second spacer.

In some embodiments, each of the two contact spacers is surrounded by the first spacer.

In some embodiments, the spacer structure further includes a third spacer surrounding an upper portion of the sidewall of the first spacer, a sidewall of the second spacer and an upper portion of each of the two contact spacers.

In some embodiments, a top portion of the third spacer, a top portion of second spacer, a top portion of the first spacer and a top portion of the bit line structure collectively form a slope.

In some embodiments, semiconductor structure further includes a landing pad disposed on the top portion of the bit line structure and covering the slope.

In some embodiments, the bit line structure includes a bottom cap layer disposed on the bit line contact, a conductive layer disposed on the bottom cap layer, and a top cap layer disposed on the conductive layer. An upper portion of the top cap layer is surrounded by the first spacer, and a lower portion of the top cap layer is surrounded by the first spacer and the second spacer.

In some embodiments, a height of the lower portion of the top cap layer is greater than a height of the upper portion of the top cap layer.

In some embodiments, the semiconductor structure further includes two cell contacts disposed on opposite sides of the bit line contact, wherein each of the two cell contacts partially contacts each of the plurality of active areas, respectively.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1-3 are views of a method of manufacturing a semiconductor structure during forming a photoresist layer according to some embodiments of this disclosure,

FIGS. 4-6 are views of a method of manufacturing a semiconductor structure during etching an upper portion of a second oxide layer according to some embodiments of this disclosure,

FIGS. 7-9 are views of a method of manufacturing a semiconductor structure during forming a spacer structure on a sidewall of each of a plurality of bit line structures according to some embodiments of this disclosure, and

FIGS. 10 and 11 are views of a method of manufacturing a semiconductor structure during forming a plurality of cell contacts and a plurality of landing pads according to some embodiments of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

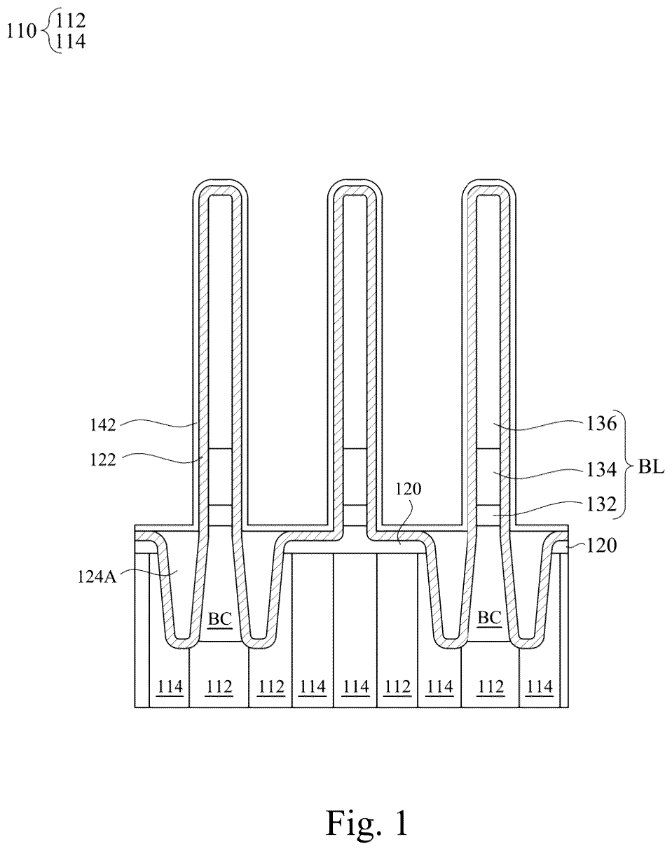

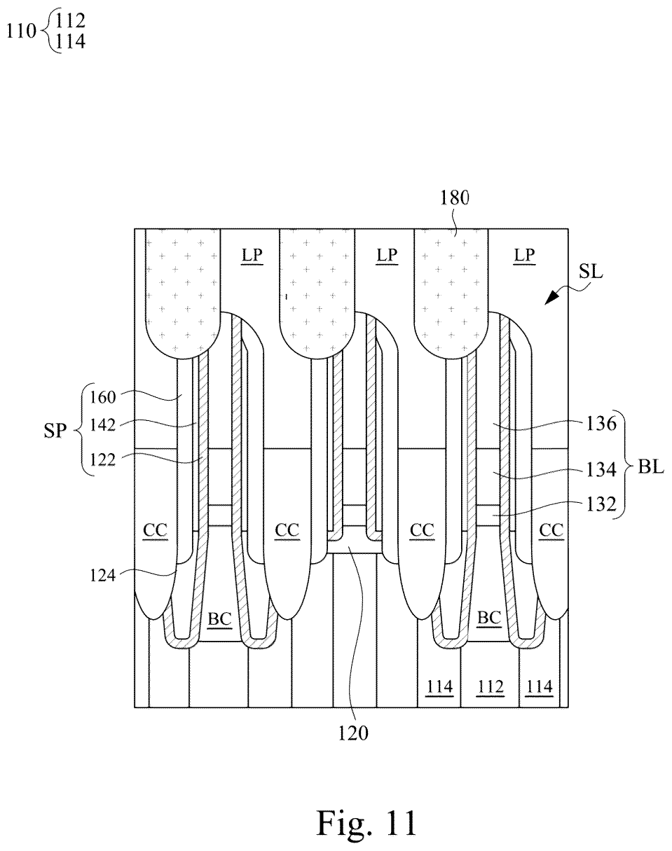

It should be noted that when the following figures, such as FIGS. 1 to 11, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 11) to completely form the semiconductor structure 100. Therefore, the present disclosure may briefly illustrate some of these additional operations or steps. Further, unless otherwise stated, the same explanations discussed for the following figures, such as FIGS. 1 to 11, apply directly to the other figures.

In related art, a void or a seam between a cell contact and a bit line structure exists, causing a storage-bit-line leakage (SBLEK). Also, as subsequent processes, the SBLEK getting worse. Therefore, embodiments of this disclosure provide a semiconductor structure and a method of manufacturing the same to solve the leakage problem caused by the void or the seam between the cell contact and the bit line structure.

Please refer to FIGS. 1-3. FIGS. 1-3 are views of a method of manufacturing a semiconductor structure during forming a photoresist layer according to some embodiments of this disclosure. In FIG. 1, a substrate 110 includes a plurality of active areas 112 and a plurality of insulation areas 114. Each of the insulation areas 114 is located between adjacent two of the active areas 112 to isolate the active areas 112 from each other. In some embodiments, the substrate 110 may include silicon, such as crystalline silicon, polycrystalline silicon, or amorphous silicon. The substrate 110 may include an elemental semiconductor, such as germanium. In some embodiments, the substrate 110 may include alloy semiconductors, such as silicon germanium, silicon germanium carbide, gallium indium phosphide, or other suitable materials. In some embodiments, the substrate 110 may include compound semiconductors, such as silicon carbide (SiC), gallium arsenide (GaAs), indium phosphide (InP), indium arsenide (InAs), or other suitable materials. Moreover, in some embodiments, the substrate 110 can optionally have a semiconductor-on-insulator (SOI) structure.

Next, each of a plurality of bit line contacts BC is formed in each of the active areas 112, respectively. Then, each of a plurality of bit line structures BL is formed on each of the plurality of bit line contacts BC, respectively. Moreover, each of the bit line structure BL includes a bottom cap layer 132 on each of the bit line contacts BC, a conductive layer 134 on the bottom cap layer 132, and a top cap layer 136 on the conductive layer 134.

Further, two recesses (not shown) are formed on opposite sides of each of the bit line contacts BC. In some embodiments, each of the two recesses exposes a sidewall of each of the bit line contacts BC. Subsequently, a first oxide layer 122 is deposited covering each of the bit line structures BL, in each of the two recesses, and over the substrate 110. In some embodiments, the first oxide layer 122 includes a low-k dielectric material, and for example, the low-k dielectric material has a low dielectric constant, 3.5. In some embodiments, the first oxide layer 122 includes SiCO. In some embodiments, an insulating layer 120 is formed between the first oxide layer 122 and the substrate 110. In some embodiments, a nitride material is deposited on the first oxide layer 122 in each of the two recesses to form a spacer material layer 124A. In some embodiments, the spacer material layer 124A includes SiN. Subsequently, a second oxide layer 142 is deposited on the first oxide layer 122 and a top surface of each of the two spacer material layers 124A. Through forming the first oxide layer 122 buried in the substrate 110 surrounding each of the two spacer material layers 124A may prevent a void or a seam from existing between each of the bit line structures and a cell contact formed later.

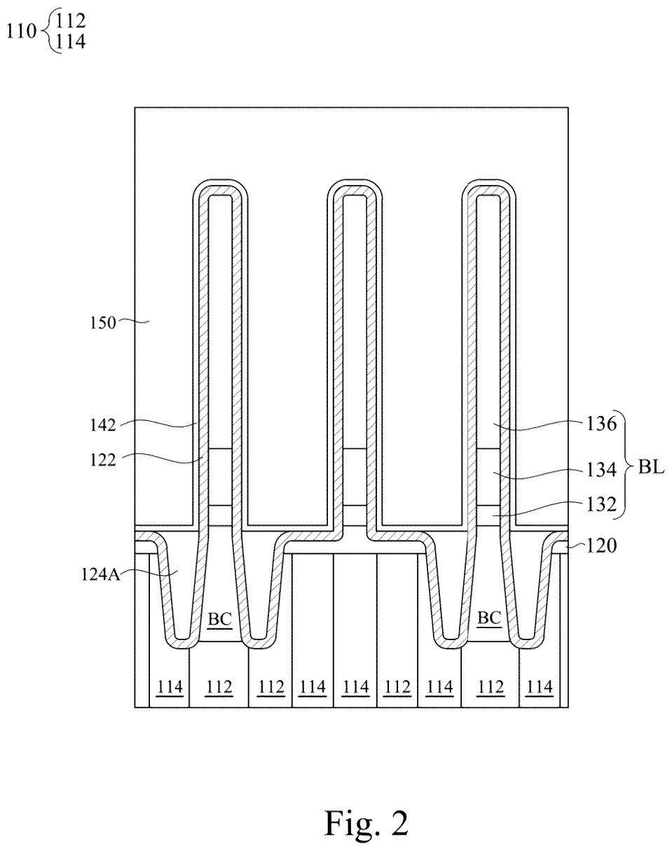

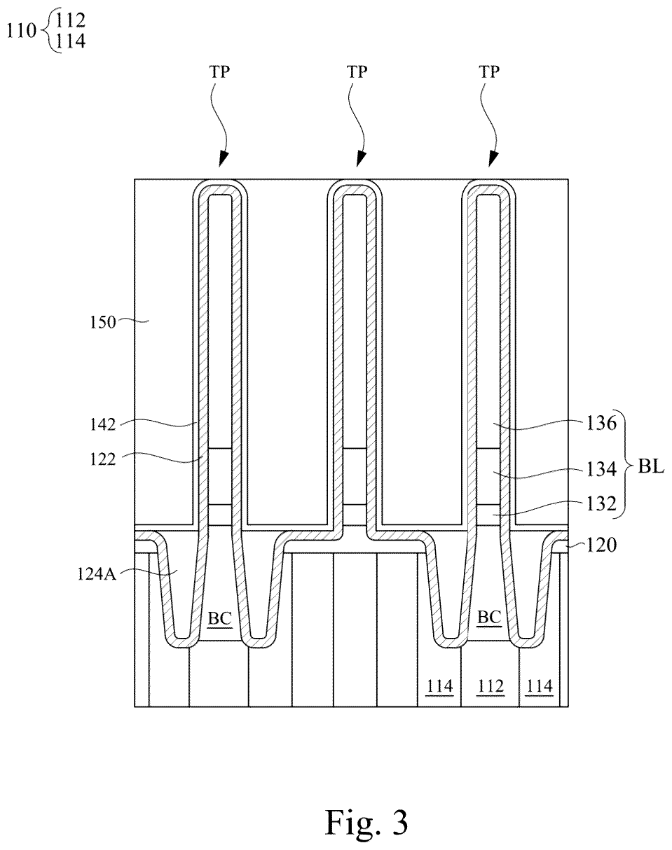

In FIG. 2, a photoresist layer 150 is formed to completely cover the second oxide layer 142. In some embodiments, the photoresist layer 150 is formed by a coating process. Subsequently, in FIG. 3, a planarization process is performed to remove a top portion of the photoresist layer 150 until exposing a top surface TP of the second oxide layer 142.

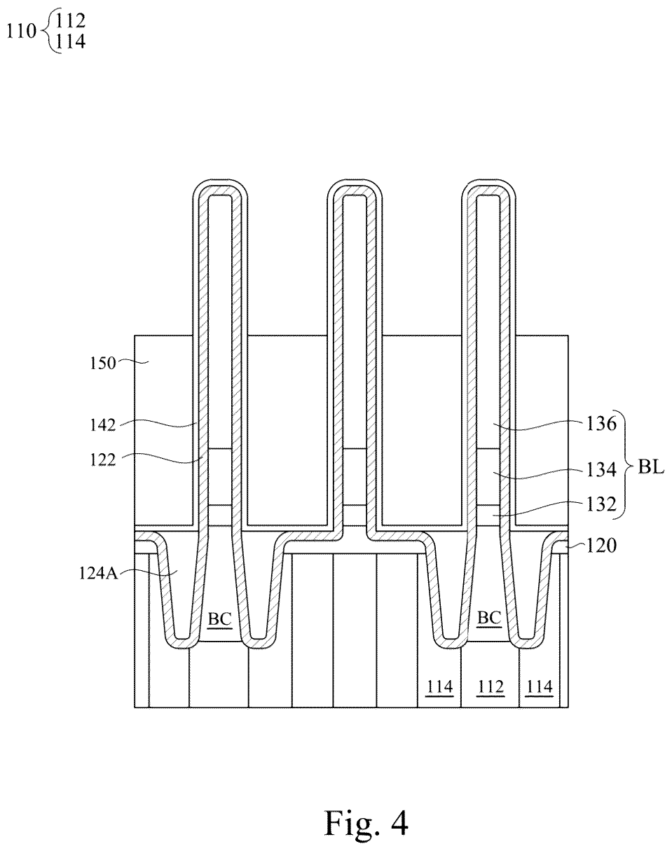

Please refer to FIGS. 4-6. FIGS. 4-6 are views of a method of manufacturing a semiconductor structure during etching an upper portion of a second oxide layer according to some embodiments of this disclosure. In FIG. 4, an upper portion of the photoresist layer 150 is removed to expose an upper portion of the second oxide layer 142. In some embodiments, the upper portion of the photoresist layer 150 is removed by an etching back process.

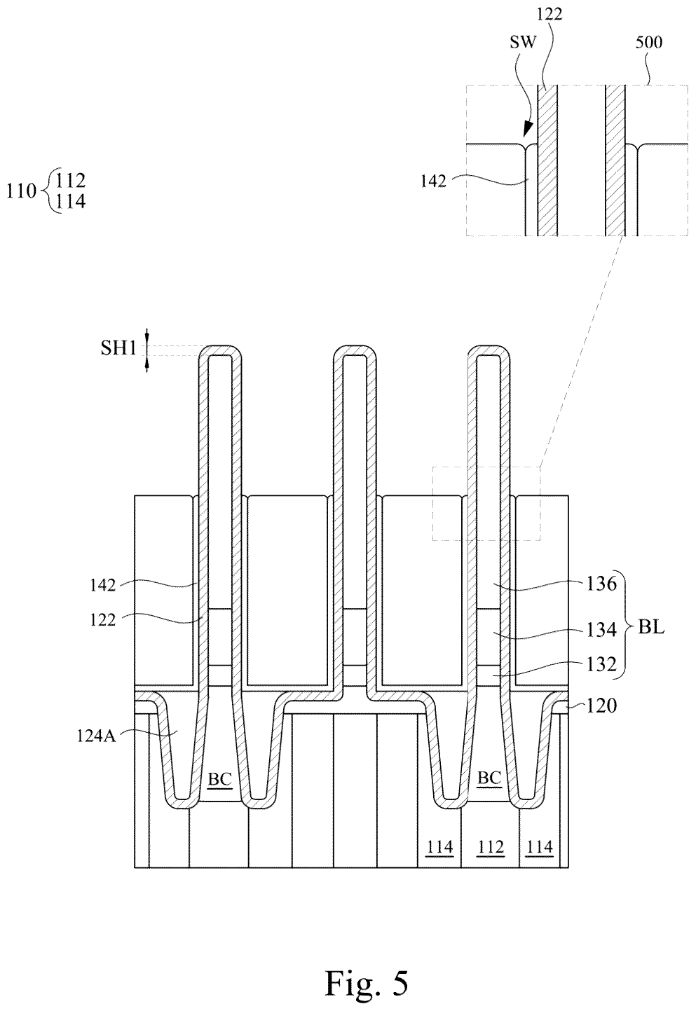

In FIG. 5, the upper portion of the second oxide layer 142 is removed to expose an upper portion of the first oxide layer 122 on each of the bit line structures BL. In some embodiments, the upper portion of the second oxide layer 142 on each of the bit line structures BL is removed by a wet etching process. In some embodiments, the wet etching process is performed by using a dilute hydrofluoric acid (DHF) etchant. In some embodiments, as shown in a dotted block enlarged view 500 of FIG. 5, a stepwise contour SW is formed at a top end of the second oxide layer 142 on the exposed upper portion of the first oxide layer 122 after removing the upper portion of the second oxide layer 142.

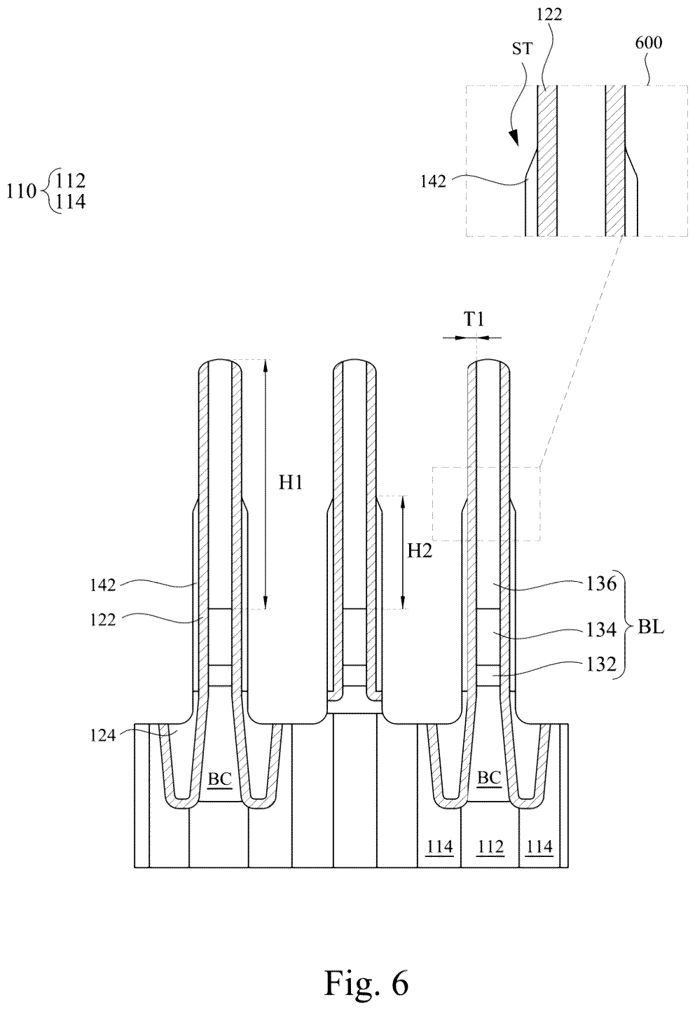

In FIG. 6, the photoresist layer 150 (as shown in FIG. 5) is removed. Next, a top portion of the first oxide layer 122 on each of the bit line structures BL is removed until exposing a portion of each of the two spacer material layers 124A to form two contact spacers 124, and the top portion of the first oxide layer 122 and each of the bit line structures BL are rounded. Thus, each of the bit line structures BL is shortened with a height SH1 (in FIG. 5) after removing the photoresist layer 150. In some embodiments, the top portion of the first oxide layer 122 is removed by an etching process, such as a dry etching process or a wet etching process, and the top cap layer 136 is substantially not lost during removing the top portion of the first oxide layer 122. Therefore, the height SH1 is substantially equal to a thickness of the top portion of the first oxide layer 122. In some embodiments, as shown in a dotted block enlarged view 600 of FIG. 6, the stepwise contour SW (as shown in FIG. 5) of the top end of the second oxide layer 142 on the exposed upper portion of the first oxide layer 122 is become into a smooth tapered contour ST at the top end of the second oxide layer 142 on the exposed upper portion of the first oxide layer 122 after removing the top portion of the first oxide layer 122. In some embodiments, a height H1 measured from a top surface of the top cap layer 136 to a top surface of the conductive layer 134 is about 120 nanometers (nm). In some embodiments, a height H2 measured from a top end of the second oxide layer 142 (after removing the top portion of the first oxide layer) to the top surface of the conductive layer 134 is about 45 nm. In some embodiments, a thickness of the first oxide layer 122 on the sidewall of each of the bit line structures BL is from about 3 nm to 4 nm, and preferably, the thickness T1 of the first oxide layer 122 on the sidewall of each of the bit line structures BL is 3.5 nm.

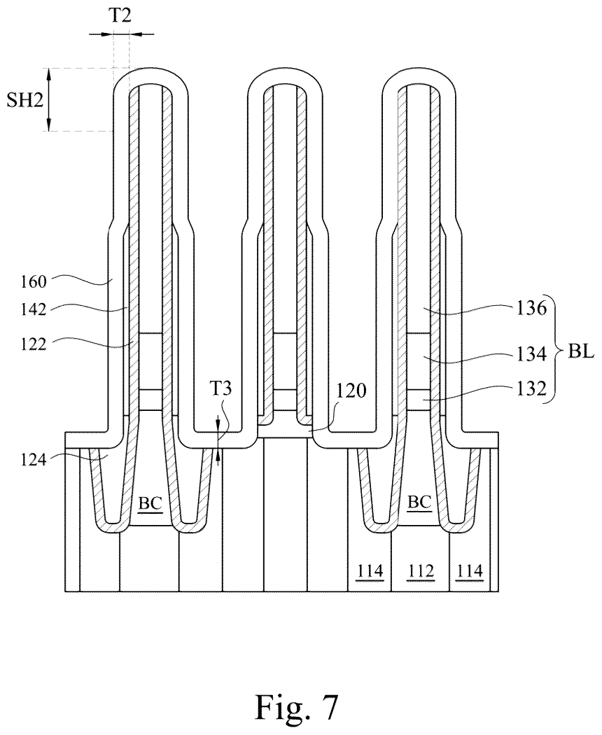

Please refer to FIGS. 7-9. FIGS. 7-9 are views of a method of manufacturing a semiconductor structure during forming a spacer structure on a sidewall of each of a plurality of bit line structures according to some embodiments of this disclosure. In FIG. 7, a first dielectric layer 160 is conformally deposited on each of the bit line structures BL, each of the exposed two contact spacers 124, a portion of the plurality of active areas 112 and a portion of each the insulation areas 114 after removing the top portion of the first oxide layer 122. In some embodiments, the first dielectric layer 160 includes nitride. The first dielectric layer 160 is configured to protect the first oxide layer 122 and the second oxide layer 142. In particular, the first dielectric layer 160 is configured to not generate the void or the seam between each of the bit line structures and each of the two cell contacts, so that the first dielectric layer 160 covering each of the two contact spacers 124 may be thick enough to prevent damage to the first oxide layer 122 during subsequent etching for forming cell contacts (described later). In some embodiments, a thickness T2 of the first dielectric layer 160 on each of the bit line structures BL is from about 5 nm to 8 nm. In some embodiments, a thickness T3 of the first dielectric layer 160 covering each of the two contact spacers 124 is about 5 nm.

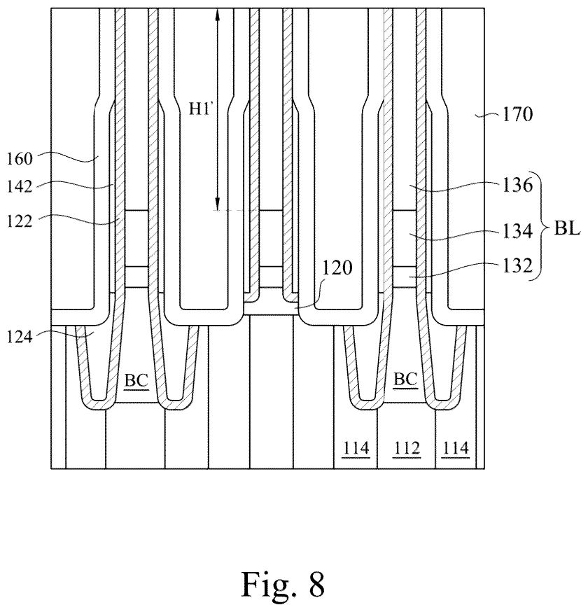

In FIG. 8, a sacrificial layer 170 is deposited on the first dielectric layer 160 to completely cover each of the bit line structures BL (figure not shown). In some embodiments, the sacrificial layer 170 includes nitride. Next, the top portion of each of the bit line structures BL, a top portion of the first oxide layer 122, a top portion of the first dielectric layer 160 and a top portion of the sacrificial layer 170 are removed. In some embodiments, the top portion of each of the bit line structures BL, the top portion of the first oxide layer 122, the top portion of the first dielectric layer 160 and the top portion of the sacrificial layer 170 are removed by an etching process, such as an etching back process. Thus, each of the bit line structures BL is shorten by a height SH2 after the etching process. In some embodiments, the height SH2 is about 20 nm. Therefore, a height H1′ measured from the top surface of the top cap layer 136 to the top surface of the conductive layer 134 is about 100 nm after the etching process. Moreover, a top surface of each of the bit line structures BL, a top surface of the first oxide layer 122, a top surface of the first dielectric layer 160 and a top surface of the sacrificial layer 170 are coplanar after the etching process. Through the sacrificial layer 170 and the etching process, the first oxide layer 122 on the sidewall of each of the bit line structures BL is not lost during shortening each of the bit line structures BL.

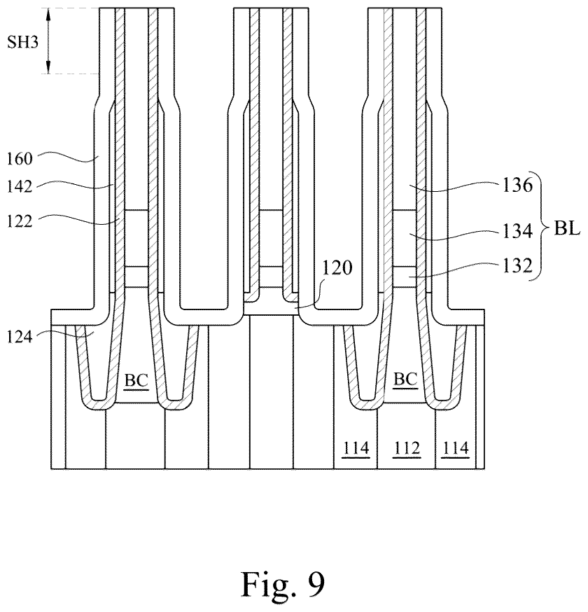

In FIG. 9, the sacrificial layer 170 is removed to expose the first dielectric layer 160. In some embodiments, the sacrificial layer 170 is removed by an etching process, such as a dry etching process or a wet etching process. Moreover, the top portion of the first dielectric layer 160 on each of the bit line structures is damaged after removing the sacrificial layer 170.

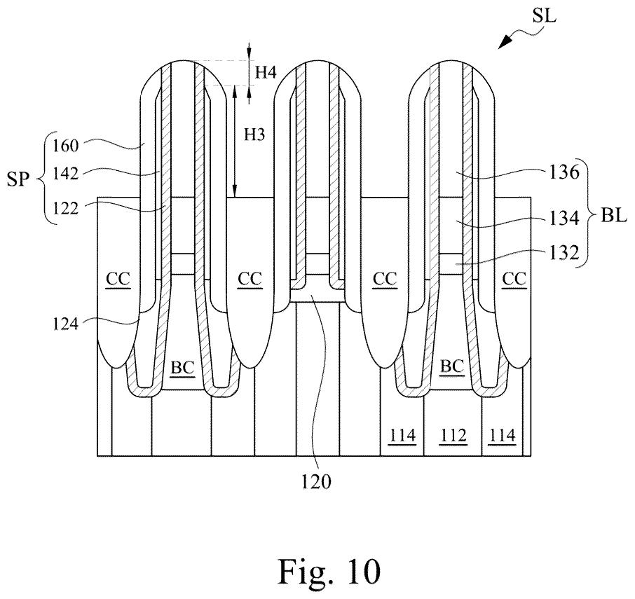

Please refer to FIGS. 10 and 11. FIGS. 10 and 11 are views of a method of manufacturing a semiconductor structure during forming a plurality of cell contacts and a plurality of landing pads according to some embodiments of this disclosure. In FIG. 10, a plurality of openings (not shown) are formed opposite sides each of the bit line contacts BC in the substrate 110 to expose a side portion of each of the two contact spacers 124. In some embodiments, the openings are formed by an etching process, such as a dry etching process or a wet etching process. Subsequently, a conductive material is formed in each of the openings to completely cover each of the bit line structures BL. Then, an upper portion of the conductive material is removed by an etching back process, such as an RIE process to form a plurality of cell contacts CC, and each of the cell contacts CC is adjacent to each of the two contact spacers 124. Specifically, each of the cell contacts is formed on opposite sides of the conductive layer 134 of each of the bit line structures BL. Moreover, the top portion of each of the bit line structures BL is also removed by a height SH3 (in FIG. 9) during removing the upper portion of the conductive material.

In addition, an upper portion of the first dielectric layer 160, an upper portion of the first oxide layer 122 and an upper portion of each of the bit line structures BL are partially removed during forming the cell contacts CC. In some embodiments, a top portion of the first dielectric layer 160, a top portion of the second oxide layer 142, a top portion of the first oxide layer 122 and a top portion of each of the bit line structures BL are collectively formed a rocket shape after partially removing the upper portion of the first dielectric layer 160, the upper portion of the first oxide layer 122 and the upper portion of each of the bit line structures BL during forming the cell contacts CC. In some embodiments, the top portion of the first dielectric layer 160, the top portion of the second oxide layer 142, the top portion of the first oxide layer 122 and the top portion of each of the bit line structures BL collectively form a slope SL after forming the cell contacts CC. In addition, after removing the sacrificial layer 170, a spacer structure SP including the first oxide layer 122, the second oxide layer 142, and the first dielectric layer 160 is formed. In this way, through removing the upper portion of the conductive material and the top portion of each of the bit line structures BL, the damage in the top portion of the first oxide layer 122 on each of the bit line structures BL during removing the sacrificial layer 170 is eliminated.

In FIG. 11, a landing pad material is formed on each of the cell contacts CC, and a top surface of the landing pad material is greater than a top surface of each of the bit line structures BL. Subsequently, the landing pad material is etched to form a plurality of openings (not shown) and a plurality of landing pads LP are formed on the top portion of each of the bit line structures BL and covering the slope SL. In some embodiments, a portion of each of the bit line structures BL and the spacer structure SL may be removed during forming the openings. Then, a second dielectric layer 180 is formed in each of the openings to separate each of the landing pads LP from each other.

As shown in FIG. 11, embodiments of this disclosure also provide a semiconductor structure 100. The semiconductor structure 100 includes a substrate 110, a bit line structure BL disposed over the substrate 110, and a spacer structure SP disposed on and extending along a sidewall of the bit line structure BL. The substrate 110 includes a plurality of active areas 112 and a plurality of insulation areas 114, and each of the insulation areas 114 is located between adjacent two of the active areas 112 to isolate the active areas 112 from each other. The spacer structure includes a first spacer 122 surrounding a sidewall of the bit line structure BL and a second spacer 142 surrounding a lower portion of a sidewall of the first spacer 122. In addition, the semiconductor structure 100 includes a bit line contact BC disposed in each of the plurality of active areas 112 and contacting a bottom portion of the second spacer 142. Moreover, a top surface of the first spacer 122 is higher than a top surface of the second spacer 142.

In some embodiments, the semiconductor structure 100 further includes two contact spacers 124 disposed on opposite sides of the bit line contact BC. In some embodiments, each of the two contact spacers 124 is surrounded by the first spacer 122. In some embodiments, the spacer structure SP further includes a third spacer 160 surrounding an upper portion of the sidewall of the first spacer 122, a sidewall of the second spacer 142 and an upper portion of each of the two contact spacers 124. In some embodiments, a top portion of the third spacer 160, a top portion of second spacer 142, a top portion of the first spacer 122 and a top portion of the bit line structure BL collectively form a slope SL. That is, the slope SL refers to a curved surface formed on a common top surface of each of the bit line structures BL, the first oxide layer 122 and the first dielectric layer 160. In some embodiments, the semiconductor structure 100 further includes a landing pad LP disposed on a top portion of the bit line structure BL and covering the slope SL.

Further, the bit line structure BL includes a bottom cap layer 132 disposed on the bit line contact BC, a conductive layer 134 disposed on the bottom cap layer 132, and a top cap layer 136 disposed on the conductive layer 134. Also, an upper portion of the top cap layer 136 is surrounded by the first spacer 122, and a lower portion of the top cap layer 136 is surrounded by the first spacer 122 and the second spacer 142. In some embodiments, a height H3 (in FIG. 10) of the lower portion of the top cap layer 136 is greater than a height H4 (in FIG. 10) of the upper portion of the top cap layer 136. In some embodiments, the semiconductor structure 100 further includes two cell contacts CC disposed on opposite sides of the bit line contact BC, and each of the two cell contacts CC partially contacts each of the plurality of active areas 112, respectively.

As stated as above, through the embodiments of this disclosure, a void or a seam may be prevented from generating between each of the bit line structures and each of the two cell contacts, improving the leakage problem of the semiconductor structure. Moreover, the damage on the top portion of each of the bit line structures formed in the manufacturing process may be eliminated, thereby avoiding damage to the semiconductor structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
providing a substrate comprising a plurality of active areas and a plurality of insulation areas, wherein each of the plurality of insulation areas is located between adjacent two of the plurality of active areas;
forming each of a plurality of bit line contacts in each of the active areas, respectively, and each of a plurality of bit line structures on each of the plurality of bit line contacts, respectively;
depositing a first oxide layer covering the plurality of bit line structures;
depositing a second oxide layer on the first oxide layer;
forming a photoresist layer to completely cover the second oxide layer; and
removing an upper portion of the second oxide layer to expose an upper portion of the first oxide layer.

2. The method of claim 1, wherein removing the upper portion of the second oxide layer comprises:
performing a planarization process on the photoresist layer until exposing a top surface of the second oxide layer after forming the photoresist layer; and
etching the upper portion of the second oxide layer to expose the upper portion of the first oxide layer.

3. The method of claim 1, further comprising:
forming two contact spacers after depositing the first oxide layer, wherein each of the two contact spacers is respectively located on opposite sides of each of the plurality of bit line contacts and surrounded by the first oxide layer.

4. The method of claim 3, further comprising:
removing the photoresist layer; and
etching a top portion of the first oxide layer on each of the plurality of bit line structures until exposing each of the two contact spacers,
wherein each of the plurality of bit line structures is shortened with a height after etching the top portion of the first oxide layer.

5. The method of claim 4, wherein the top portion of the first oxide layer and each of the plurality of bit line structures are rounded after etching the top portion of the first oxide layer.

6. The method of claim 4, wherein a stepwise contour at a top portion of the second oxide layer on the exposed upper portion of the first oxide layer is become into a smooth tapered contour at the top portion of the second oxide layer on the exposed upper portion of the first oxide layer after etching the top portion of the first oxide layer.

7. The method of claim 4, further comprising:
conformally depositing a first dielectric layer on each of the plurality of bit line structures, the exposed two contact spacers, a portion of the plurality of active areas and a portion of each the plurality of insulation areas after removing the photoresist layer;
depositing a sacrificial layer on the first dielectric layer to completely cover each of the plurality of bit line structures; and
removing a top portion of each of the plurality of bit line structures, the top portion of the first oxide layer, a top portion of the first dielectric layer and a top portion of the sacrificial layer.

8. The method of claim 7, wherein a top surface of each of the bit line structures, a top surface of the first oxide layer and a top surface of the first dielectric layer are coplanar after removing the top portion of each of the plurality of bit line structures.

9. The method of claim 7, further comprising:
removing the sacrificial layer after removing the top portion of each of the plurality of bit line structures; and
forming a plurality of cell contacts, and each of the plurality of cell contacts is respectively located between adjacent two of the plurality of bit line structures,
wherein a bottom portion of each of the plurality of cell contacts is contact with each of the plurality of active areas.

10. The method of claim 9, further comprising:
partially removing an upper portion of the first dielectric layer, the upper portion of the first oxide layer and an upper portion of each of the plurality of bit line structures during forming the plurality of cell contacts,
wherein the top portion of the first dielectric layer, a top portion of the second oxide layer, the top portion of the first oxide layer and the top portion of each of the plurality of bit line structures are collectively formed a rocket shape.

11. The method of claim 10, further comprising:
forming of a plurality landing pads on each of the plurality of cell contacts; and
forming a second dielectric layer on each of the plurality of the bit line structures to separate each of the plurality of landing pads from each other.

12. A semiconductor structure, comprising:
a substrate, comprising a plurality of active areas and a plurality of insulation areas adjacent to the active areas;
a bit line structure disposed over the substrate;
a spacer structure disposed on and extending along a sidewall of the bit line structure, wherein the spacer structure comprising:
a first spacer surrounding a sidewall of the bit line structure; and
a second spacer surrounding a lower portion of a sidewall of the first spacer,
wherein a top surface of the first spacer is higher than a top surface of the second spacer; and
a bit line contact disposed in each of the plurality of active areas and contacting a bottom portion of the second spacer.

13. The semiconductor structure of claim 12, further comprising:
two contact spacers disposed on opposite sides of the bit line contact.

14. The semiconductor structure of claim 13, wherein each of the two contact spacers is surrounded by the first spacer.

15. The semiconductor structure of claim 13, wherein the spacer structure further comprises:
a third spacer surrounding an upper portion of the sidewall of the first spacer, a sidewall of the second spacer and an upper portion of each of the two contact spacers.

16. The semiconductor structure of claim 15, wherein a top portion of the third spacer, a top portion of the second spacer, a top portion of the first spacer and a top portion of the bit line structure collectively form a slope.

17. The semiconductor structure of claim 16, further comprising:
a landing pad disposed on the top portion of the bit line structure and covering the slope.

18. The semiconductor structure of claim 13, wherein the bit line structure comprises:
a bottom cap layer disposed on the bit line contact;
a conductive layer disposed on the bottom cap layer; and
a top cap layer disposed on the conductive layer, wherein an upper portion of the top cap layer is surrounded by the first spacer, and a lower portion of the top cap layer is surrounded by the first spacer and the second spacer.

19. The semiconductor structure of claim 18, wherein a height of the lower portion of the top cap layer is greater than a height of the upper portion of the top cap layer.

20. The semiconductor structure of claim 18, further comprising:
two cell contacts disposed on opposite sides of the bit line contact, wherein each of the two cell contacts partially contacts each of the plurality of active areas. respectively.
